(19) United States
(12) Patent Application Publication
(10) Pub. No.: US 2026/0255976 A1
(43) Pub. Date: Aug. 27, 2026

(54) SEMICONDUCTOR ASSEMBLY HAVING A WARPAGE INHIBITOR IN COMBINATION WITH A SEALANT

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 19/548,216

(22) Filed: Feb. 24, 2026

Related U.S. Application Data
(60) Provisional application No. 63/763,505, filed on Feb. 26, 2025.

(51) Int. Cl. H10W 42/00; H10W 74/47; H10W 76/18

(52) U.S. Cl. CPC H10W 42/121; H10W 74/473; H10W 76/18

(57) ABSTRACT

A semiconductor assembly includes a warpage inhibitor, a semiconductor device, a sealant, and a wiring structure. The semiconductor device is electrically connected to the wiring structure and embedded in the sealant, which is combined with the warpage inhibitor to form a rigid-compliant reinforced composite configuration. The warpage inhibitor contains inorganic materials that have a suitably low coefficient of thermal expansion (CTE) and a suitably high elastic modulus to provide rigidity and reduce CTE-induced warpage between the sealant and a carrier by limiting the volume of sealant that has a CTE mismatch with the carrier.

### CROSS REFERENCE TO RELATED APPLICATION

This application claims the benefit of the filing date of U.S. Provisional Application Ser. No. 63/763,505 filed Feb. 26, 2025. The entirety of said Provisional Application is incorporated herein by reference.

### FIELD OF THE INVENTION

The present invention relates to a semiconductor assembly and, more particularly, to a semiconductor assembly having a warpage inhibitor in combination with a sealant.

### DESCRIPTION OF RELATED ART

As market trends demand thinner, smarter, and more cost-effective portable electronic devices, semiconductor packages used in such equipment are required to further reduce their size and improve electrical performance at lower cost. Among various approaches, wafer-level packaging (WLP) has emerged as a pivotal semiconductor packaging technology that enables advanced semiconductor packages with high-density electrical interconnections through efficient and highly reliable manufacturing processes.

However, in WLP technology, warpage remains an intrinsic and persistent issue that adversely affects yield and reliability. Excessive warpage impedes lithography processes from accurately patterning redistribution layer (RDL) traces. In particular, RDL fabrication relies on high-precision photolithography to form fine-pitch interconnects between semiconductor devices. As a result of warpage, the RDL layers may not properly align with the die pads, potentially resulting in faulty or incomplete electrical connections. Moreover, warpage-induced non-uniformity in layer thickness may degrade electrical performance and increase the risk of short circuits or open circuits. Accordingly, effective warpage management is critical to improving yield and overall package reliability.

### SUMMARY OF THE INVENTION

An objective of the present invention is to provide a semiconductor assembly featuring a combination of a warpage inhibitor and a sealant to form a rigid-compliant reinforced composite configuration, thereby suppressing warpage induced by sealing and by debonding from a temporary carrier, and stabilizing the overall assembly. The warpage inhibitor contains an inorganic material that has a suitably low coefficient of thermal expansion (CTE) and a suitably high elastic modulus to provide rigidity and reduce CTE-induced warpage between the sealant and the carrier by limiting the volume of sealant that typically has a CTE mismatch with the carrier.

In accordance with the foregoing and other objectives, the present invention provides a semiconductor assembly that includes a warpage inhibitor, a semiconductor device, a sealant and a wiring structure. The warpage inhibitor includes a supporting frame configured with at least one inner periphery and contains an inorganic material with an elastic modulus higher than 60 GPa and a coefficient of thermal expansion lower than 10 ppm/° C. The semiconductor device is disposed in a compartment laterally surrounded by at least one inner periphery of the supporting frame and has contact pads. The sealant fills into the compartment and laterally surrounds the semiconductor device and coats the at least one inner periphery of the supporting frame. The wiring structure includes conductive traces that extend laterally below a bottom side of the semiconductor device and are electrically connected to the contact pads of the semiconductor device.

These and other features and advantages of the present invention will be further described and more readily apparent from the detailed description of the preferred embodiments which follows.

### BRIEF DESCRIPTION OF THE DRAWINGS

The detailed description of the preferred embodiments of the present invention can best be understood when read in conjunction with the following drawings, in which:

FIG. 1 is a cross-sectional view of a warpage inhibitor on a carrier in accordance with the first embodiment of the present invention;

FIGS. 2 and 3 are cross-sectional and top perspective views, respectively, of the structure of FIG. 1 further provided with semiconductor devices in accordance with the first embodiment of the present invention;

FIG. 4 is a cross-sectional view of the structure of FIG. 2 further provided with a sealant in accordance with the first embodiment of the present invention;

FIG. 5 is a cross-sectional perspective view of the structure of FIG. 4 subjected to carrier release in accordance with the first embodiment of the present invention;

FIG. 6 is a cross-sectional perspective view of the structure of FIG. 5 further formed with a wiring structure to finish the fabrication of a semiconductor assembly in accordance with the first embodiment of the present invention;

FIG. 7 is a cross-sectional view of the structure of FIG. 6 diced into singulated assemblies in accordance with the first embodiment of the present invention;

FIG. 8 is a cross-sectional view of an individual singulated semiconductor assembly in accordance with the first embodiment of the present invention;

FIGS. 9 and 10 are cross-sectional and bottom perspective views, respectively, of the structure including semiconductor devices embedded in a hybrid shield constituted by the warpage inhibitor and the sealant in accordance with the second embodiment of the present invention;

FIG. 11 is a cross-sectional view of the structure of FIG. 9 subjected to application of a sealant, carrier debonding and formation of a wiring structure to finish the fabrication of a semiconductor assembly in accordance with the second embodiment of the present invention;

FIGS. 12 and 13 are cross-sectional and top perspective views, respectively, of a warpage inhibitor in accordance with the third embodiment of the present invention;

FIG. 14 is a cross-sectional view of the structure of FIG. 12 further provided with electronic components in accordance with the third embodiment of the present invention;

FIG. 15 is a cross-sectional view of the structure of FIG. 14 further provided with a carrier and semiconductor devices in accordance with the third embodiment of the present invention;

FIG. 16 is a cross-sectional view of the structure of FIG. 15 subjected to application of a sealant and carrier release in accordance with the third embodiment of the present invention;

FIG. 17 is a cross-sectional view of the structure of FIG. 16 further provided with a wiring structure to finish the fabrication of a semiconductor assembly in accordance with the third embodiment of the present invention;

FIG. 18 is a cross-sectional view of the structure including a wiring structure formed on a carrier in accordance with the fourth embodiment of the present invention;

FIG. 19 is a cross-sectional view of the structure of FIG. 18 further provided with a warpage inhibitor in accordance with the fourth embodiment of the present invention;

FIG. 20 is a cross-sectional view of the structure of FIG. 19 further provided with semiconductor devices in accordance with the fourth embodiment of the present invention;

FIG. 21 is a cross-sectional view of the structure of FIG. 20 subjected to application of a sealant and carrier release to finish the fabrication of a semiconductor assembly in accordance with the fourth embodiment of the present invention;

FIG. 22 is a cross-sectional view of the structure of FIG. 18 further provided with conductive pillars and a warpage inhibitor in accordance with the fifth embodiment of the present invention;

FIG. 23 is a cross-sectional view of the structure of FIG. 22 further provided with semiconductor devices in accordance with the fifth embodiment of the present invention;

FIG. 24 is a cross-sectional view of the structure of FIG. 23 further provided with a sealant in accordance with the fifth embodiment of the present invention;

FIG. 25 is a cross-sectional view of the structure of FIG. 24 subjected to removal of a portion of the sealant and the carrier to finish the fabrication of a semiconductor assembly in accordance with the fifth embodiment of the present invention;

FIG. 26 is a cross-sectional view of the structure of FIG. 25 further provided with external electronic devices in accordance with the fifth embodiment of the present invention;

FIG. 27 is a cross-sectional view of the structure including a warpage inhibitor, a wiring structure and conductive pillars provided on a carrier and semiconductor devices disposed on the wiring structure in accordance with the sixth embodiment of the present invention;

FIGS. 28 and 29 are cross-sectional and top perspective views, respectively, of the structure of FIG. 27 further provided with a sealant in accordance with the sixth embodiment of the present invention;

FIG. 30 is a cross-sectional view of the structure of FIG. 28 further provided with a plated layer in accordance with the sixth embodiment of the present invention;

FIG. 31 is a cross-sectional view of the structure of FIG. 30 further formed with a top patterned conductive layer in accordance with the sixth embodiment of the present invention;

FIG. 32 is a cross-sectional view of the structure of FIG. 31 further provided with external electronic devices in accordance with the sixth embodiment of the present invention;

FIG. 33 is a cross-sectional view of the structure including a warpage inhibitor and semiconductor devices on a carrier in accordance with the seventh embodiment of the present invention;

FIG. 34 is a cross-sectional view of the structure of FIG. 33 further provided with a sealant in accordance with the seventh embodiment of the present invention;

FIG. 35 is a cross-sectional view of the structure of FIG. 34 subjected to removal of a portion of the sealant and the carrier in accordance with the seventh embodiment of the present invention;

FIG. 36 is a cross-sectional view of the structure of FIG. 35 further provided with a wiring structure to finish the fabrication of a semiconductor assembly in accordance with the seventh embodiment of the present invention; and

FIG. 37 is a cross-sectional view of a semiconductor assembly in accordance with the eighth embodiment of the present invention.

### DETAILED DESCRIPTION OF THE PREFERRED EMBODIMENTS

Hereafter, examples will be provided to illustrate the embodiments of the present invention. The advantages and effects of the invention will become more apparent from the following description of the present invention. It should be noted that the accompanying figures are simplified and illustrative. The quantity, shape and size of components shown in the figures may be modified according to practical conditions, and the arrangement of components may be more complex. Other various aspects may also be practiced or applied in the invention, and various modifications and variations can be made without departing from the spirit of the invention based on various concepts and applications.

### Embodiment 1

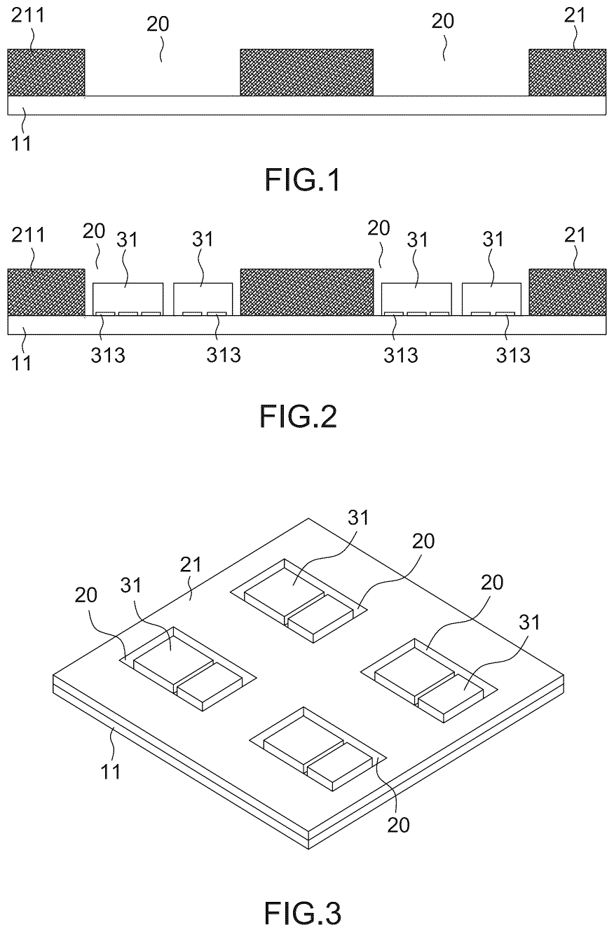

FIGS. 1-6 are schematic views showing a method of making a semiconductor assembly that includes a warpage inhibitor, semiconductor devices, a sealant and a wiring structure in accordance with the first embodiment of the present invention.

FIG. 1 is a cross-sectional view of a warpage inhibitor 21 on a carrier 11. The warpage inhibitor 21 is attached onto a top surface of a carrier 11 by an adhesive (not shown in the figure) and includes a supporting frame 211 that has inner peripheries each laterally surrounding a compartment 20 for device placement on the carrier 11. The compartments 20 can be arranged into an N×M array, such as a 2×2 array in this embodiment. The carrier 11 is typically made of silicon, glass or the like, and the supporting frame 211 contains an inorganic material configured to improve warpage management. Preferably, the inorganic material have an elastic modulus higher than 60 GPa and a coefficient of thermal expansion lower than 10 ppm/° C. For instance, the supporting frame 211 may be made of a resin/fiber composite material including inorganic fibers (such as glass fibers) dispersed in an organic resin (such as epoxy-based material). The inorganic fibers may have a volume fraction of 50% or more within the supporting frame 211. With such material properties, the supporting frame 211 provides increased rigidity and suppresses warpage by mitigating adverse effects of coefficient-of-thermal-expansion mismatch between the carrier 11 and a sealing material applied in a later-described sealing process. In addition, the incorporation of inorganic fibers may increase resistance to bending deformation by enabling efficient transfer of tensile and compressive stresses under bending loads, owing to the high aspect ratio and load-bearing continuity of the fibers, and further suppresses crack propagation through the supporting frame 211.

FIGS. 2 and 3 are cross-sectional and top perspective views, respectively, of the structure provided with semiconductor devices 31 within the compartments 20. The semiconductor devices 31, each having contact pads 313 facing in the carrier 11, are attached on the top surface of the carrier 11 and laterally surrounded by the inner peripheries of the supporting frame 211. Although this embodiment illustrates that each compartments 20 accommodates two semiconductor devices 31, the quantity of the semiconductor devices 31 within each compartment 20 is not limited thereto.

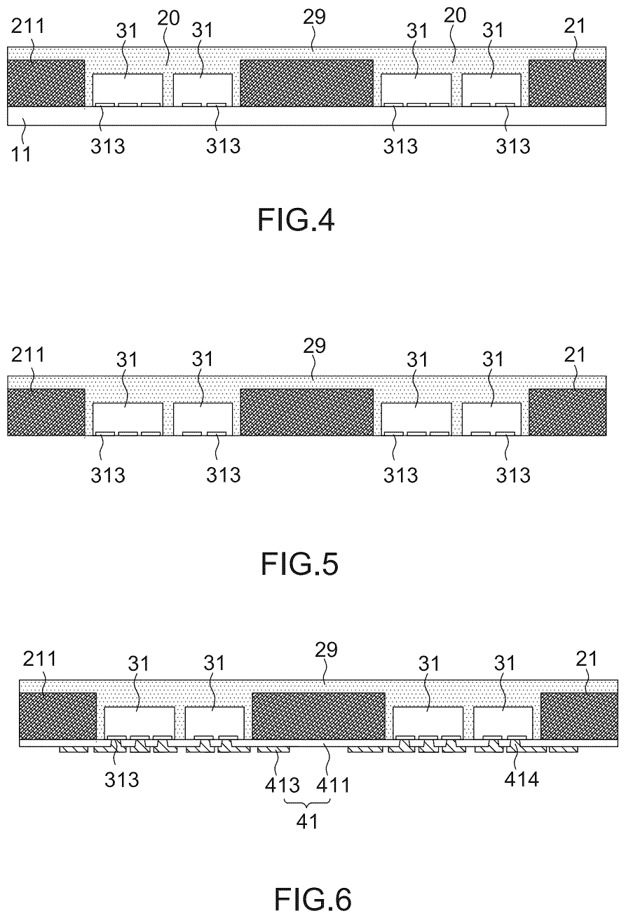

FIG. 4 is a cross-sectional view of the structure provided with a sealant 29. The sealant 29 covers top sides of the warpage inhibitor 21 and the semiconductor devices 31 and fills the compartments 20, thereby overlaying unoccupied top surfaces of the carrier 11 and conformally coating sidewalls of the semiconductor devices 31 and inner peripheries of the supporting frame 211. The sealant 29 may have an elastic modulus lower than 30 Gpa (when measured below glass transition temperature) and preferably contains inorganic filler (such as silicon oxide or alumina) in an organic material (such as epoxy-based material) so as to reduce its coefficient of thermal expansion. Compared to a configuration without the warpage inhibitor 21, the presence of the warpage inhibitor 21 reduces the available space to be filled by the sealant 29, thereby significantly reducing the overall volume of the sealant 29 and correspondingly lowering its contribution to global warpage. The warpage inhibitor 21 preferably occupies more than 10%, and more preferably more than 30%, of a planar area of a device-unoccupied region, which refers to a planar area outside a vertical projection of the semiconductor devices 31. When the occupation of the warpage inhibitor 21 exceeds such a threshold, the warpage inhibitor 21 functions as a primary load-bearing and deformation-constraining structure in the device-unoccupied region, rather than merely a local reinforcement. As a result, the warpage inhibitor 21 and the sealant 29 function cooperatively to form a reinforced composite structure, in which a rigid-compliant hybrid configuration effectively suppresses sealant-induced global warpage and stabilizes the overall assembly, including after carrier release.

FIG. 5 is a cross-sectional view of the structure after carrier release. The carrier 11 is removed from the warpage inhibitor 21, the sealant 29 and the semiconductor devices 31 through a debonding step. As the warpage inhibitor 21 and the sealant 29 cooperatively maintain structural stability of the assembly during debonding, post-debonding warpage is effectively suppressed.

FIG. 6 is a cross-sectional view of the structure provided with a wiring structure 41 in electrical connection with the semiconductor devices 31. In this illustration, the wring structure 41 includes a dielectric layer 411 and conductive traces 413. The dielectric layer 411 covers the bottom sides of the semiconductor devices 31 and the warpage inhibitor 21 and the bottom surface of the sealant 29. The conductive traces 413 are deposited to be electrically connected to the semiconductor devices 31 by, for example, metallization and then metal patterning process. Specifically, the conductive traces 413 extend laterally below the dielectric layer 411 and extend into via openings in the dielectric layer 411 to form conductive vias 414 in electrical contact with the contact pads 313 of the semiconductor devices 31.

The metallization can be executed by numerous techniques, such as electroplating, electroless plating, evaporating, sputtering or their combinations, and typically by electroless plating followed by electroplating. The metal patterning techniques include wet etching, electro-chemical etching, laser-assisted etching, and their combinations with etch masks (not shown) thereon that define the conductive traces 413. Optionally, the wring structure 41 may further include one or more additional dielectric layers and conductive traces in an alternate fashion if necessary.

At this stage, a panel-scale semiconductor assembly is accomplished and includes the semiconductor devices 31 electrically connected to the wiring structure 41 and embedded in a hybrid shield constituted by the warpage inhibitor 21 and the sealant 29.

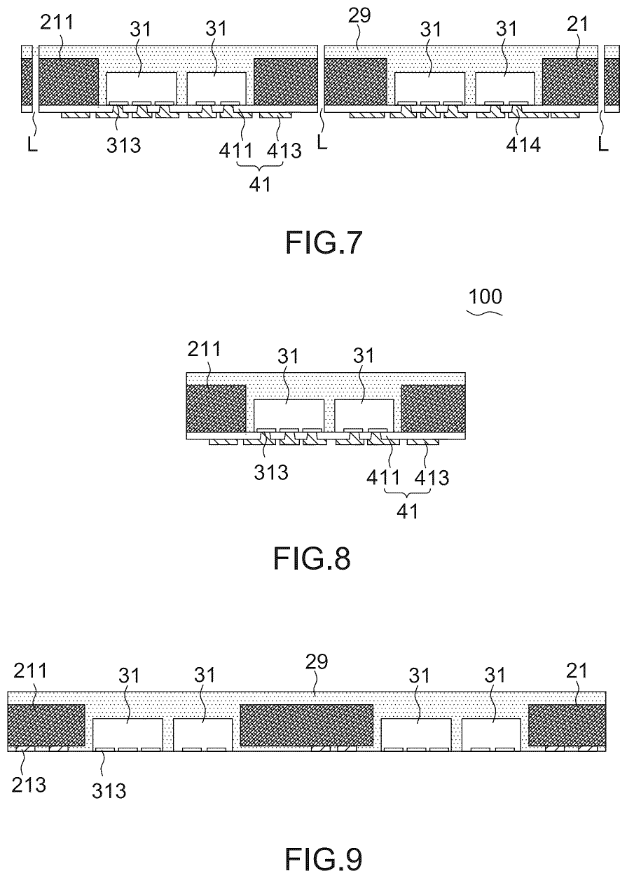

FIG. 7 is a cross-sectional view of the structure diced into singulated units. The un-singulated assembly is divided into individual units along dicing lines “L” by cutting through the sealant 29, the warpage inhibitor 21 and the wiring structure 41.

FIG. 8 is a cross-sectional view of the individual singulated semiconductor assembly 100. In this illustration, the semiconductor assembly 100 includes semiconductor devices 31 and a singulated form of the warpage inhibitor 21, the sealant 29, and the wiring structure 41.

### Embodiment 2

FIGS. 9-11 are schematic views showing a method of making a semiconductor assembly in accordance with the second embodiment of the present invention. For purposes of brevity, any description in above Embodiment 1 is incorporated herein insofar as the same is applicable, and the same description need not be repeated.

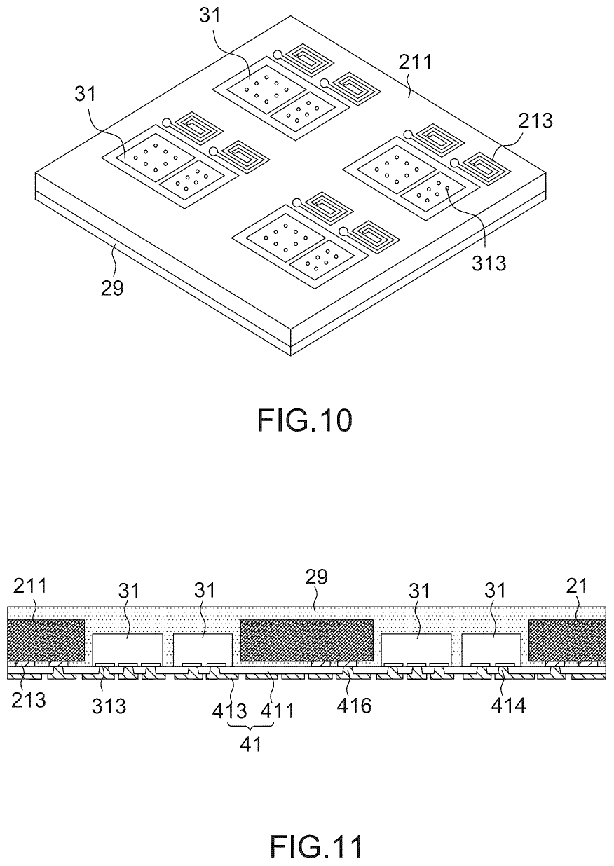

FIGS. 9 and 10 are cross-sectional and bottom perspective views, respectively, of the structure including semiconductor devices 31 embedded in a hybrid shield constituted by the warpage inhibitor 21 and the sealant 29. The panel-scale structure is similar to that illustrated in FIG. 5, except that the warpage inhibitor 21 further includes a bottom circuitry layer 213 at a bottom side of the supporting frame 211. The bottom circuitry layer 213 can be deposited on the supporting frame 211 by, for example, metallization and then metal patterning process, before the warpage inhibitor 21 is attached on the carrier 11.

FIG. 11 is a cross-sectional view of the structure provided with a wiring structure 41 in electrical connection with the semiconductor devices 31 and the bottom circuitry layer 213. In this illustration, the conductive traces 413 of the wring structure 41 include additional conductive vias 416 in electrical contact with the bottom circuitry layer 213. As a result, the wiring structure 41 is electrically connected to the contact pads 313 of the semiconductor devices 31 and the bottom circuitry layer 213 of the warpage inhibitor 21.

### Embodiment 3

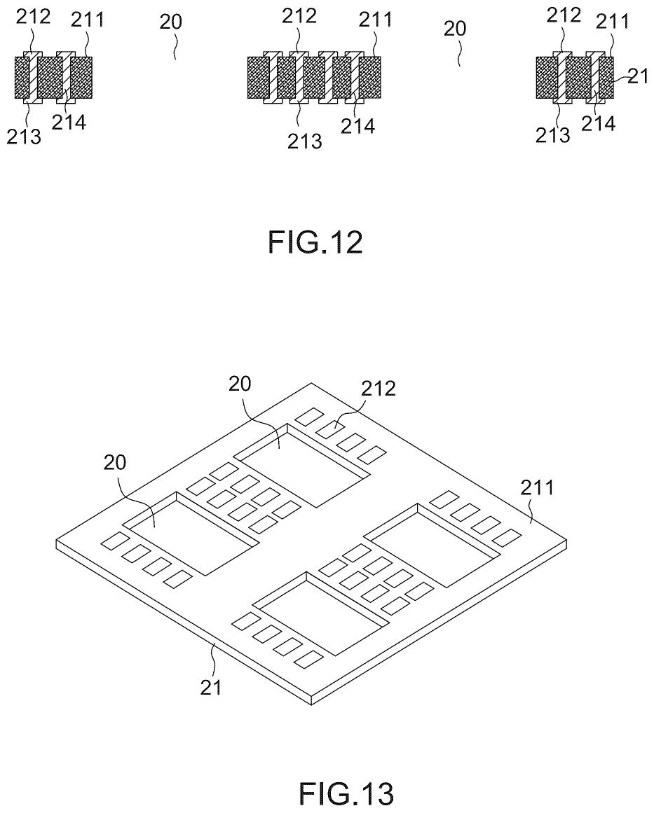

FIGS. 12-17 are schematic views showing a method of making a semiconductor assembly in accordance with the third embodiment of the present invention. For purposes of brevity, any description in above Embodiments is incorporated herein insofar as the same is applicable, and the same description need not be repeated.

FIGS. 12 and 13 are cross-sectional and top perspective views, respectively, of a warpage inhibitor 21 that includes a supporting frame 211, top and bottom circuitry layers 212 and 213, and vertically connecting elements 214. The supporting frame 211 has inner peripheries each laterally surrounding a compartment 20. The top and bottom circuitry layers 212 and 213 are deposited on the top and bottom sides of the supporting frame 211, respectively. The vertically connecting elements 214 extend through the supporting frame 211 and integrated with the top and bottom circuitry layers 212 and 213 to provide electrical connection between the top and bottom circuitry layers 212 and 213.

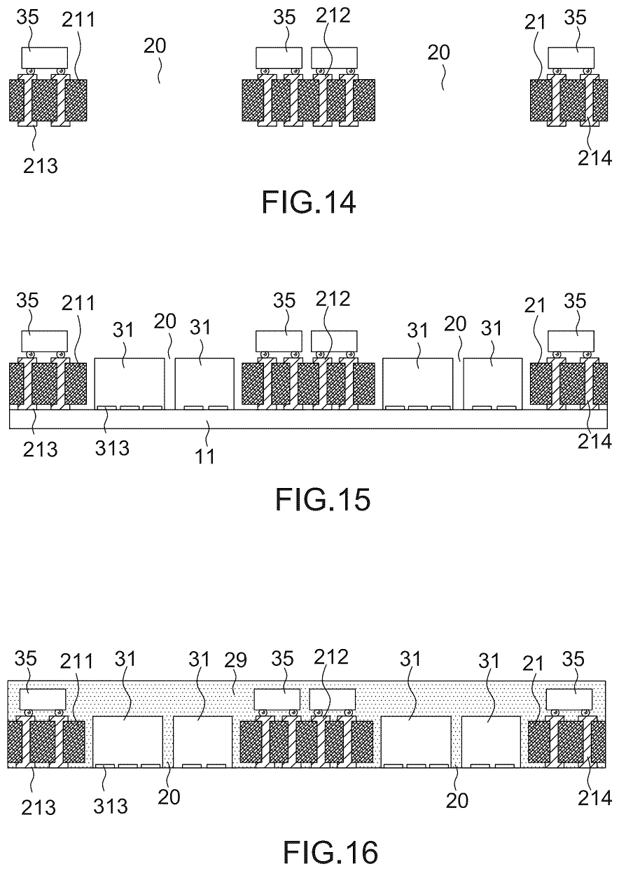

FIG. 14 is a cross-sectional view of the structure provided with electronic components 35 on the warpage inhibitor 21. The electronic components 35 are disposed above the top side of the warpage inhibitor 21 and electrically connected to the top circuitry layer 212. Depending on design requirements, the electronic components 35 may be active components (such as transistors, diodes and the like) or passive components (such as capacitors, resistors, inductors and the like).

FIG. 15 is a cross-sectional view of the structure provided with a carrier 11, to which the warpage inhibitor 21 and the semiconductor devices 31 are attached. The semiconductor devices 31 are located within the compartments 20 defined by the supporting frame 211. The bottom circuitry layer 213 of the warpage inhibitor 21 and the contact pads 313 of the semiconductor devices 31 face in the carrier 11.

FIG. 16 is a cross-sectional view of the structure after application of a sealant 29 and subsequent carrier release. The sealant 29 covers the warpage inhibitor 21, the semiconductor devices 31 and the electronic components 35 from above and fills the compartments 20. The bottom circuitry layer 213 of the warpage inhibitor 21 and the contact pads 313 of the semiconductor devices 31 are exposed from below.

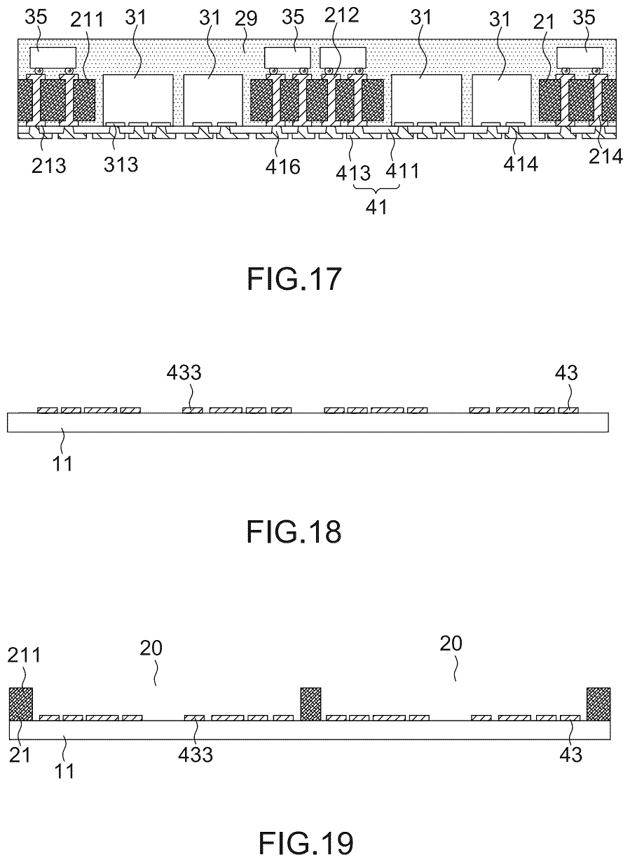

FIG. 17 is a cross-sectional view of the structure provided with a wiring structure 41 in electrical connection with the semiconductor devices 31 and the bottom circuitry layer 213. By conductive traces 413 of the wiring structure 41 and the top and bottom circuitry layers 212, 213 and the vertically connecting elements 214 of the warpage inhibitor 21, the semiconductor devices 31 can be electrically connected to the electronic components 35.

### Embodiment 4

FIGS. 18-21 are schematic views showing a method of making a semiconductor assembly in accordance with the fourth embodiment of the present invention. For purposes of brevity, any description in above Embodiments is incorporated herein insofar as the same is applicable, and the same description need not be repeated.

FIG. 18 is a cross-sectional view of the structure including a wiring structure 43 formed on a carrier 11. The wiring structure 43 includes conductive traces 433 arranged in N×M array (such as 2×2 array) of regions, with the conductive traces 433 having the same trace pattern in each region. The conductive traces 433 are typically made of copper, aluminum, alloy 42, iron, nickel, silver, gold, combinations thereof, alloys thereof or any other suitable metals, and can be deposited on the carrier 11 by, for example, electrolytic plating.

FIG. 19 is a cross-sectional view of the structure provided with a warpage inhibitor 21 on the carrier 11. The warpage inhibitor 21 defines an N×M array (such as 2×2 array) of compartments 20 with the conductive traces 433 accommodated therein. The conductive traces 433 typically have the same trace pattern in each compartment 20.

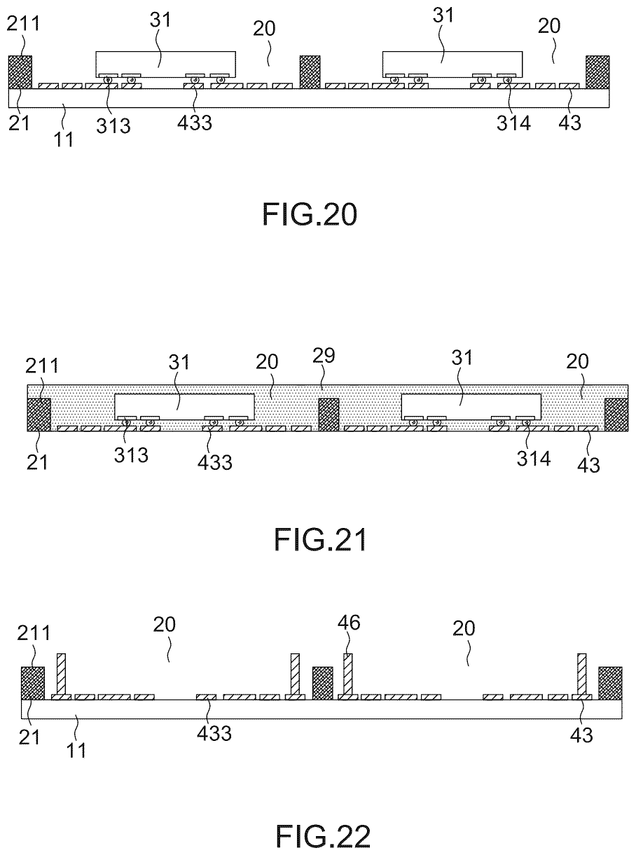

FIG. 20 is a cross-sectional view of the structure provided with semiconductor devices 31 within the compartments 20. The semiconductor devices 31 are mounted on the wiring structure 43 and each have contract pads 313 facing in the wiring structure 43 and electrically connected to the conductive traces 433 through conductive bumps 314. In this illustration, each of the semiconductor devices 31 is laterally surrounded by a respective one of the inner peripheries of the warpage inhibitor 21.

FIG. 21 is a cross-sectional view of the structure after application of the sealant 29 and subsequent carrier release. The sealant 29 covers the warpage inhibitor 21 and the semiconductor devices 31 from above, and fills the compartments 20. As a result, the semiconductor devices 31 and the conductive traces 433 are embedded in the sealant 29, and the conductive traces 433 have bottom surfaces exposed to enable next-level interconnection or further routing. In this illustration, the bottom surfaces of the conductive traces 433 are substantially coplanar with the bottom surface of the sealant 29. Optionally, the wiring structure 43 may further include one or more dielectric layers and additional conductive traces in an alternate fashion if needed. For instance, after carrier removal, a dielectric layer (not shown in the figure) can be provided below the warpage inhibitor 21 and the conductive traces 433, and additional conductive traces (not shown in the figure) are deposited and extend laterally below the dielectric layer and include conductive vias in the dielectric layer for electrical connection with the conductive traces 433.

### Embodiment 5

FIGS. 22-25 are schematic views showing a method of making a semiconductor assembly in accordance with the fifth embodiment of the present invention. For purposes of brevity, any description in above Embodiments is incorporated herein insofar as the same is applicable, and the same description need not be repeated.

FIG. 22 is a cross-sectional view of the structure of FIG. 18 provided with conductive pillars 46 and a warpage inhibitor 21. After the conductive pillars 46 are deposited on the conductive traces 433 by, for example, electrolytic plating, the warpage inhibitor 21 is attached on the carrier 11 using an adhesive (not shown in the figure) and defines compartments 20. In this illustration, the conductive traces 433 and conductive pillars 46 are arranged in the same configuration in each compartment 20.

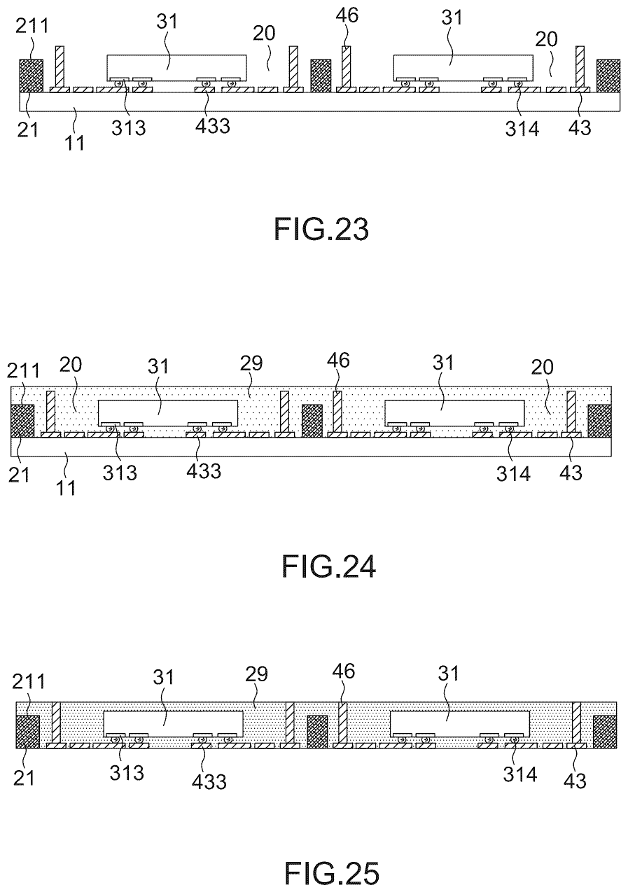

FIG. 23 is a cross-sectional view of the structure provided with semiconductor devices 31 within the compartments 20. The semiconductor devices 31 are electrically connected to the conductive traces 433 through conductive bumps 314 in contact with contact pads 313 of the semiconductor devices 31 and the conductive traces 433. In this illustration, each of the semiconductor devices 31 is laterally surrounded by the respective conductive pillars 46 and the respective inner periphery of the warpage inhibitor 21.

FIG. 24 is a cross-sectional view of the structure provided with a sealant 29. The sealant 29 covers the carrier 11, the warpage inhibitor 21, the semiconductor devices 31, the wiring structure 43, and the conductive pillars 46 from above. As a result, the warpage inhibitor 21, the semiconductor devices 31, the conductive traces 433 and the conductive pillars 46 are embedded in the sealant 29.

FIG. 25 is a cross-sectional view of the structure after removal of a portion of the sealant 29 and the carrier 11. After the sealant 29 is lapped from above to expose top sides of the conductive pillars 46, the carrier 11 is removed from the warpage inhibitor 21, the sealant 29 and the wiring structure 43. At this stage, the top sides of the conductive pillars 46 are substantially coplanar with the top surface of the sealant 29, and the conductive traces 433 are exposed from below. Optionally, the wiring structure 43 may further include one or more dielectric layers and additional conductive traces below the warpage inhibitor 21 and the sealant 29 if needed.

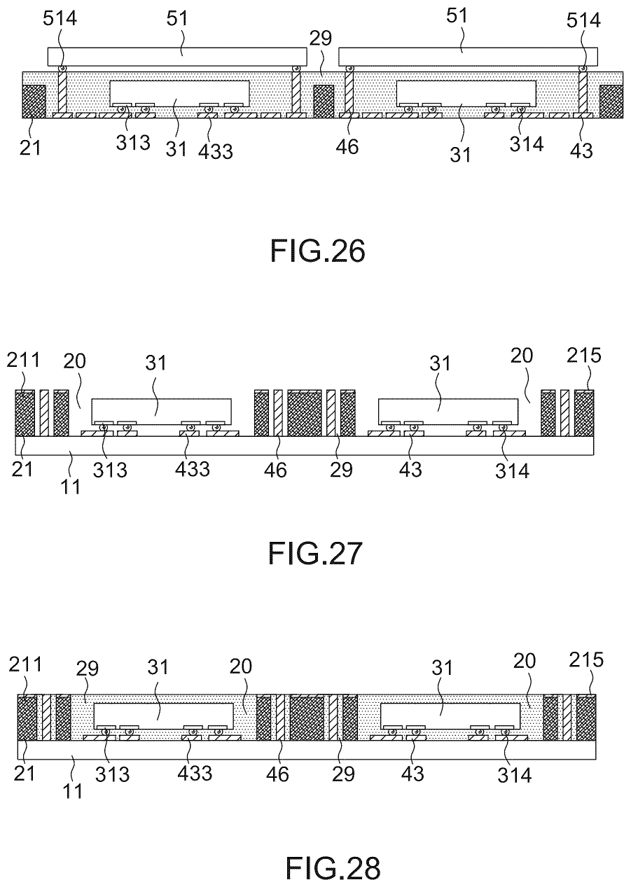

FIG. 26 is a cross-sectional view of the structure provided with external electronic devices 51. The external electronic devices 51 are attached above the conductive pillars 46 through solder balls 514. As a result, the semiconductor devices 31 can be electrically connected to the external electronic devices 51 by the wiring structure 43 and the conductive pillars 46.

### Embodiment 6

FIGS. 27-31 are schematic views showing a method of making a semiconductor assembly in accordance with the sixth embodiment of the present invention. For purposes of brevity, any description in above Embodiments is incorporated herein insofar as the same is applicable, and the same description need not be repeated.

FIG. 27 is a cross-sectional view of the structure including a warpage inhibitor 21, a wiring structure 43 and conductive pillars 46 provided on a carrier 11 and semiconductor devices 31 disposed on the wiring structure 43. After the wiring structure 43 and the conductive pillars 46 are deposited on the carrier 11, the semiconductor devices 31 are face-down mounted on the wiring structure 43 by conductive bumps 314 and the warpage inhibitor 21 is attached on the carrier 11 using an adhesive (not shown in the figure). In this embodiment, the warpage inhibitor 21 includes a supporting frame 211 and a metal layer 215 on a top side of the supporting frame 211. The supporting frame 211 defines compartments 20 for accommodating the semiconductor devices 31 and the conductive pillars 46. In this illustration, the metal layer 215 has a top surface substantially coplanar with the top sides of the conductive pillars 46.

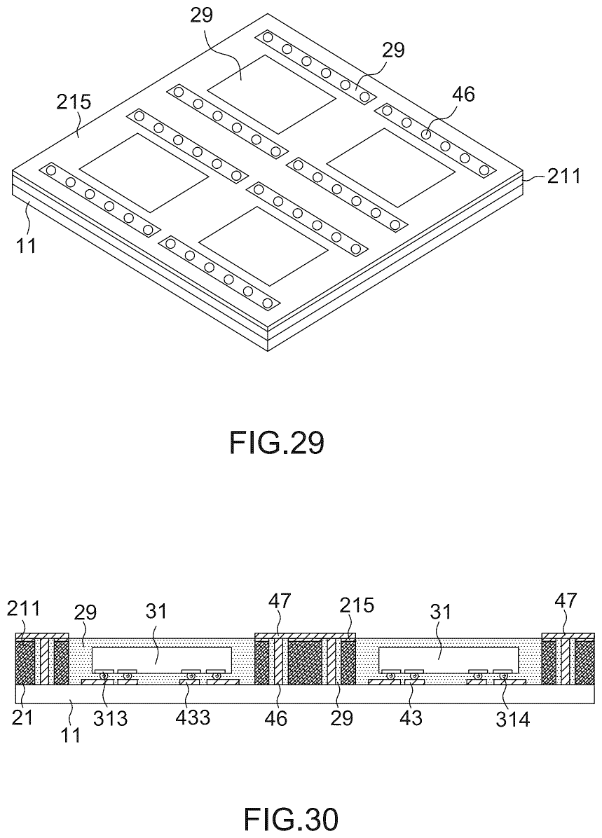

FIGS. 28 and 29 are cross-sectional and top perspective views, respectively, of the structure provided with a sealant 29. The sealant 29 fills the compartments 20 to seal the semiconductor devices 31 and to conformally coat sidewalls of the conductive pillars 46 and the inner peripheries of the warpage inhibitor 21. In this illustration, the sealant 29 has a top surface substantially coplanar with the top surface of the metal layer 215 and the top sides of the conductive pillars 46.

FIG. 30 is a cross-sectional view of the structure provided with a plated layer 47. The plated layer 47 is deposited by, for example, electroless plating and then electroplating. As a result, the plated layer 47 extends laterally on the top sides of the conductive pillars 46 and the top surface of the metal layer 215 as well as the top surface of the sealant 29 between the conductive pillars 46 and the inner peripheries of the warpage inhibitor 21.

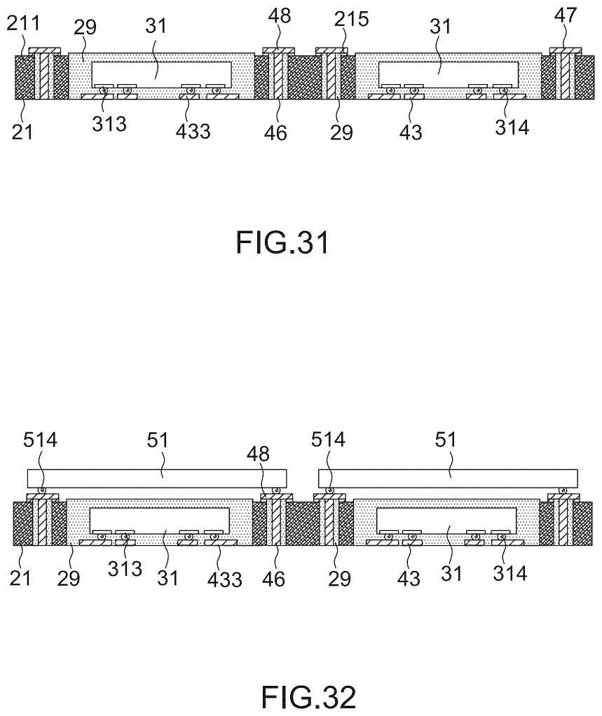

FIG. 31 is a cross-sectional view of the structure after formation of the top patterned conductive layer 48 and subsequent carrier release. The top patterned conductive layer 48 is formed in electrical connection with the conductive pillars 46 by patterning both the plated layer 47 and the metal layer 215, and the conductive traces 43 and the conductive pillars 46 are exposed from below by removing the carrier 11. As can be seen, the top patterned conductive layer 48 laterally extends on the top sides of the conductive pillars 46 and the top surface of the sealant 29 surrounding the conductive pillars 46 and further laterally extends above the top side of the supporting frame 211. In this illustration, the top patterned conductive layer 48 consists of the plated layer 47 on the sealant 29 and the conductive pillars 46, whereas over the supporting frame 211, it includes both the plated layer 47 and the metal layer 215. As a result, the top patterned conductive layer 48 is thicker on the supporting frame 211 than on the sealant 29 and the conductive pillars 46.

FIG. 32 is a cross-sectional view of the structure provided with external electronic devices 51. The external electronic devices 51 are mounted over the top patterned conductive layer 48 through solder balls 514. As a result, the external electronic devices 51 can be electrically connected to the conductive pillars 46 by the top patterned conductive layer 48.

### Embodiment 7

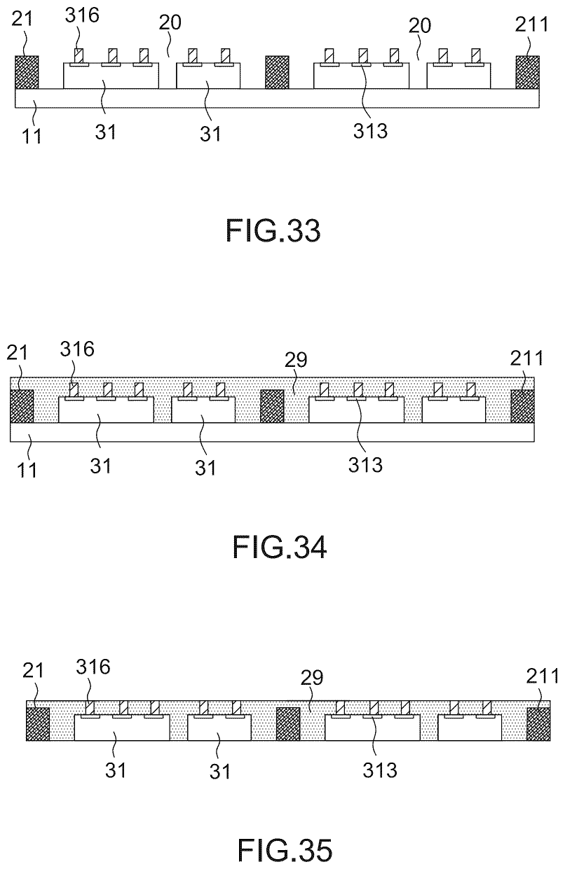

FIGS. 33-36 are schematic views showing a method of making a semiconductor assembly in accordance with the seventh embodiment of the present invention. For purposes of brevity, any description in above Embodiments is incorporated herein insofar as the same is applicable, and the same description need not be repeated.

FIG. 33 is a cross-sectional view of the structure including a warpage inhibitor 21 and semiconductor devices 31 on a carrier 11. Before the attachment of the semiconductor devices 31 to the carrier 11, conductive studs 316 are prefabricated on contact pads 313 of the semiconductor devices 31 using, for example, electroplating. The semiconductor devices 31 are face-up mounted on the carrier 11 and located within the compartments 20 defined by the inner peripheries of the warpage inhibitor 21.

FIG. 34 is a cross-sectional view of the structure provided with a sealant 29. The sealant 29 covers the warpage inhibitor 21, the semiconductor devices 31 and the conductive studs 316 from above. As a result, the warpage inhibitor 21, the semiconductor devices 31 and the conductive studs 316 are embedded in the sealant 29.

FIG. 35 is a cross-sectional view of the structure after removal of a portion of the sealant 29 and the carrier 11. After the sealant 29 is lapped from above to expose top sides of the conductive stubs 316, the carrier 11 is removed from the warpage inhibitor 21, the sealant 29 and the semiconductor devices 31. At this stage, the top sides of the conductive stubs 316 are substantially coplanar with the top surface of the sealant 29, and the bottom sides of the semiconductor devices 31 are exposed and substantially coplanar with the bottom surface of the sealant 29 and the bottom side of the warpage inhibitor 21.

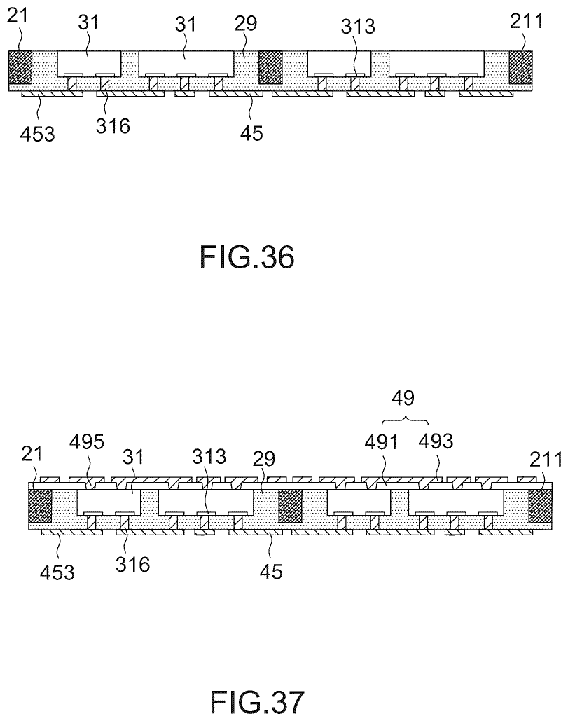

FIG. 36 is a cross-sectional view of the structure after formation of a wiring structure 45 and inversion of the structure. The wiring structure 45 includes conductive traces 453 that extend laterally underneath the bottom surface of the sealant 29 and the bottom sides of the conductive stubs 316. As a result, the semiconductor devices 31 are electrically connected to the wiring structure 45 through the conductive stubs 316.

### Embodiment 8

FIG. 37 is a cross-sectional view of a semiconductor assembly in accordance with the eighth embodiment of the present invention. For purposes of brevity, any description in above Embodiments is incorporated herein insofar as the same is applicable, and the same description need not be repeated.

The semiconductor assembly of this embodiment is similar to that illustrated in FIG. 36, except that a routing structure 49 is further provided to facilitate thermal dissipation of the semiconductor devices 31.. In this illustration, the routing structure 49 includes a dielectric layers 491 and conductive traces 493. The dielectric layer 491 covers the top sides of the semiconductor devices 31 and the warpage inhibitor 21 and the top surface of the sealant 29. The conductive traces 493 extend laterally over dielectric layer 491 and extend into via openings in the dielectric layer 491 to form metallized vias 495 in thermal conduction with the semiconductor devices 31.

As illustrated in the aforementioned embodiments, a distinctive semiconductor assembly is configured to exhibit improved reliability, which mainly includes a warpage inhibitor, one or more semiconductor devices, a sealant and a wiring structure. Optionally, the semiconductor assembly may further include conductive pillars embedded in the sealant and a top patterned conductive layer on a top surface of the sealant and top sides of the conductive pillars.

The semiconductor assemblies described above are merely exemplary. Numerous other embodiments are contemplated. In addition, the embodiments described above can be mixed-and-matched with one another and with other embodiments depending on design and reliability considerations. The semiconductor device can share or not share the compartment with other semiconductor devices. For instance, a compartment can accommodate a single semiconductor device, or numerous semiconductor devices can be disposed with a single compartment.

In the manufacturing of the semiconductor assembly, the semiconductor devices and the warpage inhibitor can be first attached onto a carrier, followed by application of the sealant, and then carrier release and formation of the wiring structure. Alternatively, the wiring structure is first formed on the carrier, followed by attachment of the semiconductor devices and the warpage inhibitor, application of the sealant and then carrier release. As a result, the combination of the warpage inhibitor and the sealant forms a reinforced composite structure, in which a rigid-compliant hybrid configuration effectively suppresses sealant-induced global warpage and stabilizes the overall assembly.

The warpage inhibitor can include a supporting frame configured with one or more inner peripheries laterally surrounding one or more semiconductor devices. In an assembly fabricated using a chip-first approach, the bottom side of the warpage inhibitor may be substantially coplanar with the bottom surface of the sealant and the bottom side of the semiconductor device in a face-down chip-first process, or the top side of the warpage inhibitor may be substantially coplanar with the top surface of the sealant and the top side of the semiconductor device in a face-up chip-first process. Preferably, the warpage inhibitor occupies more than 10% (more preferably more than 30%) of a planar area of a device-unoccupied region and contains an inorganic material. For instance, the warpage inhibitor may be made of a resin/fiber composite material including inorganic fibers (such as glass fibers) in an organic resin (such as epoxy-based material), wherein the inorganic fibers have an elastic modulus higher than 60 GPa and a coefficient of thermal expansion lower than 10 ppm/° C. The inorganic fibers may have a volume fraction of 50% or more within the supporting frame to provide desired effect. As such, sufficient coverage by the warpage inhibitor having a relatively low CTE and a relatively high elastic modulus can suppress warpage by mitigating the adverse effects of CTE mismatch between the carrier and the sealant, while also providing rigidity. Further, the warpage inhibitor may include a bottom circuitry layer at a bottom side of the supporting frame. Additionally, the warpage inhibitor may further include a top circuitry layer at a top side of the supporting frame and vertically connecting elements extending through the supporting frame and having top and bottom sides in electrical connection with the top and bottom circuitry layers, respectively. Depending on design requirements, one or more electronic components (such as transistors, diodes, capacitors, resistors, inductors, or other active or passive components) can be disposed on the top circuitry layer of the warpage inhibitor. Through the combination of the top and bottom circuitry layers, the vertically connecting elements, and the wiring structure, the electronic components can be electrically connected to the semiconductor devices.

The sealant covers and contacts and conformally coats sidewalls of the semiconductor devices as well as the inner peripheries of the supporting frame. Typically, the sealant is made of a different material than the supporting frame. In one or more preferred embodiments, the sealant has an elastic modulus lower than 30 Gpa (when measured below glass transition temperature), and is composed of an organic material incorporating electrically insulative inorganic fillers with low coefficients of thermal expansion (CTE) to alleviate its coefficient of thermal expansion.

The wiring structure, disposed below the semiconductor device, includes conductive traces electrically connected to contact pads of the semiconductor device through, for example, conductive vias, conductive bumps or conductive stubs. In instances where the warpage inhibitor includes a bottom circuitry layer, the wiring structure may be further electrically connected to the bottom circuitry layer of the warpage inhibitor. For instance, the wiring structure may include at least one dielectric layer and at least one layer of conductive traces. The dielectric layer and the conductive traces of the wiring structure are serially formed in an alternate fashion and can be in repetition if needed for further signal routing. The innermost dielectric layer of the wiring structure contacts the sealant and extends laterally below the semiconductor device, the warpage inhibitor and the sealant. The innermost conductive traces of the wiring structure extend laterally below the innermost dielectric layer and extend into via openings in the innermost dielectric layer to form conductive vias in contact with and electrical connection with the contact pads of the semiconductor device and optionally the bottom circuitry layer (if present) of the warpage inhibitor. As an alternative, the wiring structure may include conductive traces embedded in the sealant and electrically connected to the contact pads of the semiconductor device through conductive bumps. The bottom surface of the embedded conductive traces typically is substantially coplanar with the bottom surface of the sealant and may be exposed for next-level interconnection or be in electrical contact with conductive vias of additional conductive traces. Optionally, the wiring structure may further include a dielectric layer below the embedded conductive traces, the sealant and the warpage inhibitor and the additional conductive traces that extend laterally below the dielectric layer and extend into via openings in the dielectric layer to form conductive vias in contact with the bottom surface of the embedded conductive traces. For the assembly in which the semiconductor device is electrically connected to the wiring structure through conducive stubs, the conductive traces of the wiring structure extend laterally below the bottom surface of the sealant and contact the conducive stubs embedded in the sealant. The bottom side of the embedded conductive stubs typically is substantially coplanar with the bottom surface of the sealant. Optionally, a routing structure may be further formed above the top sides of the semiconductor device and the warpage inhibitor. For instance, the routing structure may include at least one dielectric layer and at least one layer of conductive traces. The dielectric layer and the conductive traces of the routing structure are serially formed in an alternate fashion and can be in repetition if needed. The innermost dielectric layer of the routing structure contacts the sealant and extends laterally above the semiconductor device, the warpage inhibitor and the sealant. The innermost conductive traces of the routing structure extend laterally over the innermost dielectric layer and extend into via openings in the innermost dielectric layer to form metallized vias in contact with the top side of the semiconductor device and optionally the top circuitry layer (if present) of the warpage inhibitor.

The optional conductive pillars have sidewalls that are covered and conformally coated by the sealant and provide vertical connection between the top and bottom sides of the assembly. The bottom sides of the conductive pillars may be in contact with the top surfaces of embedded conductive traces (if present), or be substantially coplanar with a bottom surface of the sealant and exposed for next-level interconnection or in contact with the wiring structure. The top sides of the conductive pillars may be in electrical connection with a top patterned conductive layer (if present), or be substantially coplanar with a top surface of the sealant and exposed for next-level interconnection or in contact with the routing structure (if present). In one or more preferred embodiments, the top patterned conductive layer is thicker on the supporting frame than on the sealant and the conductive pillars.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The semiconductor device can be a packaged or unpackaged chip. Furthermore, the semiconductor device can be a bare chip, or a wafer level packaged die, etc.

The term “cover” refers to incomplete or complete coverage in a vertical and/or lateral direction and includes contact and non-contact situations. For example, in a preferred embodiment, the sealant located around the conductive pillars has selected portions that are covered by the optional top patterned conductive layer, while other portions remain exposed and are not covered by the optional top patterned conductive layer.

The term “surround” refers to relative position between elements regardless of whether the elements are spaced from or adjacent to one another. For instance, in a preferred embodiment, the inner periphery of the warpage inhibitor laterally surrounds the semiconductor device regardless of whether another element (such as the sealant) is between the semiconductor device and the warpage inhibitor.

The terms “mounted” and “attached” include contact and non-contact with a single or multiple element(s). For instance, in a preferred embodiment, the warpage inhibitor is attached on the carrier and is separated from the carrier by the adhesive.

The phrases “electrical connection” and “electrically connected” refer to direct and indirect electrical connection. For instance, in a preferred embodiment, the semiconductor device is electrically connected to the wiring structure by the conductive bumps but does not contact the wiring structure.

The spatially relative terms, such as “top”, “bottom”, “below”, “above”, “lower”, “upper” and the like, may be used herein for ease of description to describe one element or feature's relationship to another element(s) or feature(s) as illustrated in the figures. The spatially relative terms are intended to encompass different orientations of the assembly in use or operation in addition to the orientation depicted in the figures. For example, if the assembly in the figures is turned over, elements described as “below” other elements or features would then be oriented “above” the other elements or features, and “bottom” surfaces would become “top” surfaces. Likewise, in the appended claims, although the side of the semiconductor device where the contact pads are located is described as a bottom side, such description is intended to include orientations in which the contact pads of the semiconductor device face upward, such that the contact pads are located at a top side of the semiconductor device and the wiring structure is formed above the semiconductor device. Thus, the term “below” can encompass both an orientation of above and below. The assembly may be otherwise oriented (rotated 90 degrees or at other orientations) and the spatially relative descriptions used herein interpreted accordingly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A semiconductor assembly, comprising a warpage inhibitor, a semiconductor device, a sealant and a wiring structure, wherein:
the warpage inhibitor includes a supporting frame configured with at least one inner periphery and contains an inorganic material with elastic modulus higher than 60 GPa and a coefficient of thermal expansion lower than 10 ppm/° C.;
the semiconductor device is disposed in a compartment laterally surrounded by the at least one inner periphery of the supporting frame and has contact pads;
the sealant fills into the compartment and laterally surrounds the semiconductor device and coats the at least one inner periphery of the supporting frame; and
the wiring structure includes conductive traces that extend laterally below a bottom side of the semiconductor device and are electrically connected to the contact pads of the semiconductor device.

2. The semiconductor assembly of claim 1, wherein the warpage inhibitor occupies more than 10% of a planar area of a device-unoccupied region.

3. The semiconductor assembly of claim 1, wherein the sealant contains inorganic filler and has an elastic modulus lower than 30 Gpa when measured below glass transition temperature.

4. The semiconductor assembly of claim 1, wherein the supporting frame is made of a resin/fiber composite material including inorganic fibers dispersed in an organic resin, the inorganic fibers having a volume fraction of 50% or more within the supporting frame.

5. The semiconductor assembly of claim 4, wherein the inorganic fibers are glass fibers.

6. The semiconductor assembly of claim 1, wherein the conductive traces have conductive vias in electrical connection with the contact pads of the semiconductor device.

7. The semiconductor assembly of claim 6, wherein the wiring structure further includes a dielectric layer disposed below the semiconductor device, the warpage inhibitor and the sealant, and the conductive traces extend laterally below the dielectric layer and extend into via openings in the dielectric layer to form the conductive vias.

8. The semiconductor assembly of claim 1, wherein the conductive traces extend laterally below a bottom surface of the sealant and are electrically connected to the contact pads of the semiconductor device through conductive stubs embedded in the sealant and each having a bottom side substantially coplanar with the bottom surface of the sealant.

9. The semiconductor assembly of claim 1, wherein the conductive traces are embedded in the sealant and electrically connected to the contact pads of the semiconductor device through conductive bumps and each has a bottom surface substantially coplanar with a bottom surface of the sealant.

10. The semiconductor assembly of claim 1, wherein the warpage inhibitor further includes a bottom circuitry layer that is disposed at a bottom side of the supporting frame and electrically connected to the conductive traces.

11. The semiconductor assembly of claim 10, wherein the warpage inhibitor further includes a top circuitry layer and vertically connecting elements, wherein the top circuitry layer is disposed at a top side of the supporting frame, the vertically connecting elements extend through the supporting frame to provide electrical connections between the top circuitry layer and the bottom circuitry layer.

12. The semiconductor assembly of claim 11, further comprising one or more electronic components disposed above the top side of the warpage inhibitor and electrically connected to the top circuitry layer and embedded in the sealant.

13. The semiconductor assembly of claim 1, further comprising conductive pillars that are embedded in the sealant and each has a top side substantially coplanar with a top surface of the sealant.

14. The semiconductor assembly of claim 13, wherein the conductive pillars are disposed on top surfaces of the conductive traces, and the conductive traces are embedded in the sealant and each has a bottom surface substantially coplanar with a bottom surface of the sealant.

15. The semiconductor assembly of claim 13, wherein each of the conductive pillars has a bottom side substantially coplanar with a bottom surface of the sealant.

16. The semiconductor assembly of claim 13, further comprising a top patterned conductive layer that laterally extends on the top surface of the sealant and the top sides of the conductive pillars and further laterally extends above a top side of the supporting frame.
